(19) United States
(12) Patent Application Publication
(10) Pub. No.: US 2013/0069136 A1
(43) Pub. Date: Mar. 21, 2013

(54) SINGLE-GATE NON-VOLATILE FLASH MEMORY CELL, MEMORY DEVICE AND MANUFACTURING METHOD THEREOF

(71) Applicants: Jianhong Mao, Shanghai (CN); Fengqin Han, Shanghai (CN)

(72) Inventors: Jianhong Mao, Shanghai (CN); Fengqin Han, Shanghai (CN)

(21) Appl. No.: 13/637,019

(22) PCT Filed: Jan. 26, 2011
(86) PCT No.: PCT/CN2011/070640

§ 371 Date: Nov. 27, 2012

(30) Foreign Application Priority Data
Mar. 25, 2010 (CN) 201010135706.0

(51) Int. Cl. H01L 29/788; H01L 21/336

(52) U.S. Cl. 257/316; 438/257; 257/E29.3; 257/E21.422

(57) ABSTRACT

A single-gate non-volatile flash memory cell, a memory device including the memory cell, and a manufacturing method thereof are provided. The memory cell includes a semiconductor structure and a movable switch (200), wherein the semiconductor structure includes a floating-gate structure, and an interlayer dielectric layer (130) with an opening (1204) through which the floating-gate structure is exposed; the movable switch (200) includes a support component (210) and a conductive interconnection component (220),the support component (210) is located on the periphery of the conductive interconnection component (220) and connected with the interlayer dielectric layer (130), and the conductive interconnection component (220) is floating over the opening (1024). When a voltage is applied to the conductive interconnection component (220), the conductive interconnection component (220) is electrically connected with the floating-gate structure, so that the advantages of simple control circuit, low manufacturing cost, high reliability, low power consumption and high efficiency are obtained.

### CROSS REFERENCE TO RALATED APPLICATIONS

The present application claims priority to Chinese Patent Application No. 201010135706.0, filed on Mar. 25, 2010, and entitled “SINGLE-GATE NON-VOLATILE FLASH MEMORY CELL, MEMORY DEVICE AND MENUFACTURING METHOD THEREOF”, the entire disclosure of which is incorporated herein by reference.

### FIELD OF THE DISCLOSURE

The present disclosure relates to semiconductor memory devices, and more particularly, to a single-gate non-volatile flash memory cell, a memory device and a manufacturing method thereof.

### BACKGROUND OF THE DISCLOSURE

Normally, semiconductor memory devices adapted for data storage includes two kinds, volatile memory devices and non-volatile memory devices. Volatile memory devices lose their stored data when power off, but non-volatile memory devices maintain data even after power off. Currently there are several types of non-volatile memory devices, such as electrically programmable read-only-memory (EPROM) devices, electrically erasable programmable read-only-memory (EEPROM) devices and flash memory devices. Compared with other non-volatile memory devices, flash memory devices feature the advantage of non-volatility, low power consumption, electrically rewritable capability and low cost. Therefore, non-volatile memory devices are widely used in various fields including embedded systems such as personal computers, PC peripheral equipment, telecom switches, cellular phones, network interconnection devices, instruments and vehicle devices. Non-volatile memory devices can also be utilized in novel products relating to voice, image or data storage, such as digital cameras, digital voice recorders and personal digital assistants.

For example, FIG. 1 illustrates a schematic cross-sectional view of a conventional single-gate memory cell. The single-gate memory cell is formed with an N type substrate 12 or an N type well. A first region 14, a second region 16 and a third region 18 which are all P+ type are disposed in the N-type well or the N type substrate 12. The first region 14, the second region 16 and the third region 18 are spaced at a distance with each other, thereby defining a first channel region 24 between the first region 14 and the second region 16, and a second channel region 26 between the second region 16 and the third region 18. Above the first channel region 24, there is a control gate 20 which is isolated and insulated from the first channel region 24. The control gate 20 overlays the first channel region 24. However, the control gate 20 doesn't overlap or just overlaps a portion of the first region 14 and the second region 16. Above the second channel region 26, there is a floating-gate 22 which is isolated and insulated from the second channel region 26. The floating-gate 22 overlays the second channel region 26. However, the floating-gate 22 doesn't overlay or just overlaps a portion of the second region 16 and the third region 18. In a write operation, a positive voltage, for example, +5 V, is applied to the first region 14, a relatively low grounded voltage is applied to the third region 18, and another low ground voltage is applied to the control gate 24. Because a P type transistor is formed in the first region 14, the second region 16 and the first channel region 24, the first channel region 24 may be in conduction by applying a voltage of 0 V to the control gate 20. Therefore, the voltage of +5 V applied to the first region 14 is transferred to the second region 16 through the first channel region 24. In the second region 16, holes are injected to the floating-gate 22 due to the hot carrier effect, thereby accomplishing the write operation.

Conventionally, an erase operation is performed under mechanism of hot electron tunneling or electron tunneling, in which a high operating voltage is necessary, for example, from about 7 V to about 20 V. Therefore, high-voltage devices are necessarily involved in the non-volatile memory devices, resulting in a complicated manufacturing process and higher costs. Besides, repeated erase operations with the hot electron tunneling or electron tunneling may lead to the transistor failure.

### BRIEF SUMMARY OF THE DISCLOSURE

Embodiments of the present disclosure provide a single-gate non-volatile flash memory cell and a method for forming the same, to improve the reliability of the memory cell.

To achieve the objection, one embodiment of the present disclosure provides a single-gate non-volatile flash memory cell. The memory cell includes a semiconductor structure which includes a substrate, a doped well with a first conducting type in the substrate, a controlling-gate transistor and a floating-gate transistor which are in and on the doped well. The controlling-gate transistor's source and the floating-gate transistor's drain share a same doped region, the floating-gate transistor includes a floating-gate structure, and an interlayer dielectric (ILD) layer is disposed on the semiconductor structure.

The memory cell by further includes a movable switch disposed above the floating-gate structure. There is an opening corresponding to the movable switch in the ILD layer, and the opening exposes the floating-gate structure. The movable switch includes: a support component and a conductive interconnection component. One end of the support component connects to the border of the conductive interconnection component, another end of the support component connects to the ILD layer, so that the conductive interconnection component suspends above the opening. The conductive interconnection component electrically connects to the floating-gate structure when a voltage is applied to the conductive interconnection component.

Optionally, the floating-gate structure includes a floating-gate part and a floating-gate extension part.

The movable switch is disposed above the floating-gate extension part. There is an opening corresponding to the movable switch in the ILD layer, and the opening exposes the floating-gate extension part. The movable switch includes a support component and a conductive interconnection component. One end of the support component connects to the border of the conductive interconnection component, another end of the support component connects to the ILD layer, so that the conductive interconnection component suspends above the opening. The conductive interconnection component electrically connects to the floating-gate extension part when a voltage is applied to the conductive interconnection component.

Optionally, the first doping type is N type and a second doping type is P type.

Optionally, the first doping type is P type and a second doping type is N type.

Optionally, the support component includes insulating material, the support component are configured as pins distributed on two symmetrical opposite sides of the conductive interconnection component, the one end the support component connecting to the conductive interconnection component is disposed under the conductive interconnection component, and the another end of the support component connecting to the ILD layer is disposed on the ILD layer.

Optionally, the floating-gate structure includes a floating-gate and an insulating layer on the floating-gate, the opening includes a first portion in the ILD layer and a second portion which is in the insulating layer of the floating-gate extension part and corresponds to the first portion's central region, and the opening's second portion corresponds to the first portion's central region.

Optionally, the conductive interconnection component includes a convex portion towards the floating-gate extension part, and the convex portion corresponds to the opening's second portion in the floating-gate extension part.

Optionally, the conductive interconnection component corresponds to the opening's central region.

Optionally, the conductive interconnection component includes metal.

A single-gate non-volatile flash memory device including an array of above mentioned single-gate non-volatile flash memory cells is provided according to another embodiment.

Another embodiment provides a method for forming a single-gate non-volatile flash memory cell, including:

Providing a semiconductor structure, wherein the semiconductor structure comprises a substrate, a doped well with a first conducting type in the substrate, a controlling-gate transistor and a floating-gate transistor which are in and on the doped well, wherein the controlling-gate transistor's source and the floating-gate transistor's drain share a same doped region, the floating-gate transistor comprises a floating-gate structure, and an interlayer dielectric layer is disposed on the semiconductor structure;

Etching the semiconductor structure to form a first opening in the ILD layer on the floating-gate structure;

Forming a sacrificial layer to fill the first opening;

Forming a barrier layer on the ILD layer to cover portions of the sacrificial layer;

Etching the barrier layer to form a second opening in the barrier layer which exposes the sacrificial layer;

Forming a conductive layer on the barrier layer on the sacrificial layer to cover the second opening; and

Removing the sacrificial layer in the first opening.

Optionally, the floating-gate structure includes a floating-gate part and a floating-gate extension part, and forming the first opening in the ILD layer on the floating-gate structure is to form the first opening in the ILD layer on the floating-gate extension part.

Optionally, the floating-gate structure includes a floating-gate and an insulating layer on the floating-gate, and the step of etching the semiconductor structure to form the first opening includes:

Etching the ILD layer to form a first portion of the first opening; and

Etching the insulating layer in the first opening's first portion to form the opening's second portion in the insulating layer exposed by the first opening's first portion.

Optionally, the barrier layer corresponds to the first opening's central region, and the second opening corresponds to the first opening's central region.

Optionally, the insulating layer includes silicon nitride.

Optionally, the conductive layer includes metal.

Compared with the prior art, embodiments of the present disclosure have advantageous below:

A moveable switch is configured above the floating-gate structure, and an opening corresponding to the movable switch is disposed in the ILD layer to expose floating-gate structure. The movable switch includes: a support component and a conductive interconnection component. The support component is attached on the conductive interconnection component's periphery and connected with the ILD layer, the conductive interconnection component is floating over the opening by the support component, and the conductive interconnection component is electrically connected with the floating-gate extension part through the opening when a voltage is applied to the conductive interconnection component. Therefore, the write and erase operations may be performed by applying a voltage on the movable switch, which may hinder the conductive interconnection component electrically connected with the floating-gate structure. Therefore, charges may be stored into or erased from the floating-gate structure to write or erase the memory cell. Charging or discharging the floating-gate in a floating-gate transistor by a controlling-gate transistor is no longer need. The floating-gate is charged or discharged by utilizing the movable switch which may be controlled by a relatively low voltage (3 V to 6 V). Therefore, high voltages are no longer needed, neither the formation of high voltage devices in the control circuit, which simplifies the structure of the control circuit more simple. In addition, because the erase operation doesn't need high voltages, the device reliability may be increased. Moreover, the power consumption generated by the current in a conventional write operation performed to the floating-gate by utilizing hot electrons may be avoided. Further, the write and erase operations are performed directly to the floating-gate in the embodiments, thereby significantly reducing the operation period and improving the working efficiency.

### BRIEF DESCRIPTION OF THE DRAWINGS

The above described and other features and advantages will become more apparent to those of ordinary skill in the art by describing in detail exemplary embodiments with reference to the attached drawings. The same reference numbers may be used in different drawings to identify the same or similar elements. The figures are not drawn to scale, and it is noted that the drawings are provided for illustrative purposes only.

FIG. 1 is a schematic cross-sectional view of a conventional single-gate memory cell;

FIG. 2 is a schematic structural view of a single-gate non-volatile flash memory cell according to an embodiment of the present disclosure;

FIG. 3 is a schematic cross-sectional view illustrating the structure shown in FIG. 2 along A-A′ direction;

FIG. 4 is a schematic cross-sectional view illustrating the structure shown in FIG. 2 along B-B′ direction;

FIG. 5 is a schematic cross-sectional view illustrating the structure shown in FIG. 2 along C-C′ direction;

FIG. 6 is a flow chart illustrating a method for forming a single-gate non-volatile flash memory cell according to an embodiment of the present disclosure; and

FIGS. 7 to 11 are schematic cross-sectional views of intermediate structures illustrating a method for forming a single-gate non-volatile flash memory cell according to an embodiment of the present disclosure.

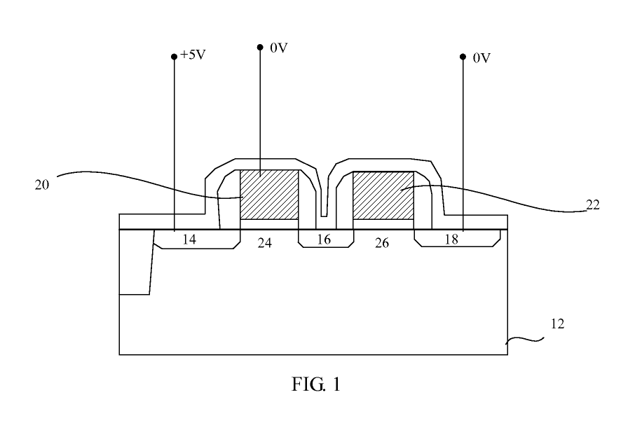

### DETAILED DESCRIPTION OF THE DISCLOSURE

As described in the background of the present disclosure, the conventional single-gate memory cell is erased by applying the mechanism of hot electron tunneling or electron tunneling, in which a high operating voltage is necessary. Normally the operating voltage of an erase operation ranges from about 7 V to about 20 V. Therefore, high-voltage devices are necessarily involved in non-volatile memory devices manufacturing, resulting in a complicated manufacturing process. Erasing a memory cell provided by an embodiment of the present disclosure is realized by a movable switch to charge/discharge the memory cell, which simplifies the control circuit and reduces the manufacturing costs. Besides, in the conventional single-gate memory cell, the hot electron tunneling and electron tunneling occurring in repeated erase operations may lead to the transistor failure. While, in the embodiment of the present disclosure, a high voltage is no longer required, this may improve the reliability of the product. Further, writing and erasing the conventional single-gate memory cell needs to open the memory cell's channel, and hot electrons are generated when a large current passes through the channel, which may increase the power consumption. While, in the embodiment of the present disclosure, the power consumed in the write operation performed to the floating-gate by applying hot electrons may be avoided. The conventional erase operation is realized by applying the mechanism of the electron tunneling effect generated when the gate oxide layer is biased with a high voltage, which leads to a low operating speed. While, in the embodiment of the present disclosure, the erase or write operation is directly performed to the floating-gate by utilizing the movable switch, so that the operating speed can be increased.

In order to clarify the objects, characteristics and advantages of the disclosure, embodiments of the disclosure will be interpreted in detail in combination with accompanied drawings. Although the present disclosure is disclosed hereinafter with reference to preferred embodiments in detail, it also can be implemented in other different embodiments and those skilled in the art may modify and vary the embodiments without departing from the spirit and scope of the present disclosure. Therefore, the present disclosure should not be limited by the embodiments disclosed herein.

Besides, embodiments of the present disclosure will be illustrated with reference to the accompanying drawings. In the accompanying drawings, for convenience of description, the sizes of respective components may not be drawn based on actual scales. The accompanying drawings are merely examples which should not limit the scope of the present disclosure. Besides, three-dimensional sizes of length, width and depth should be included in real manufacturing.

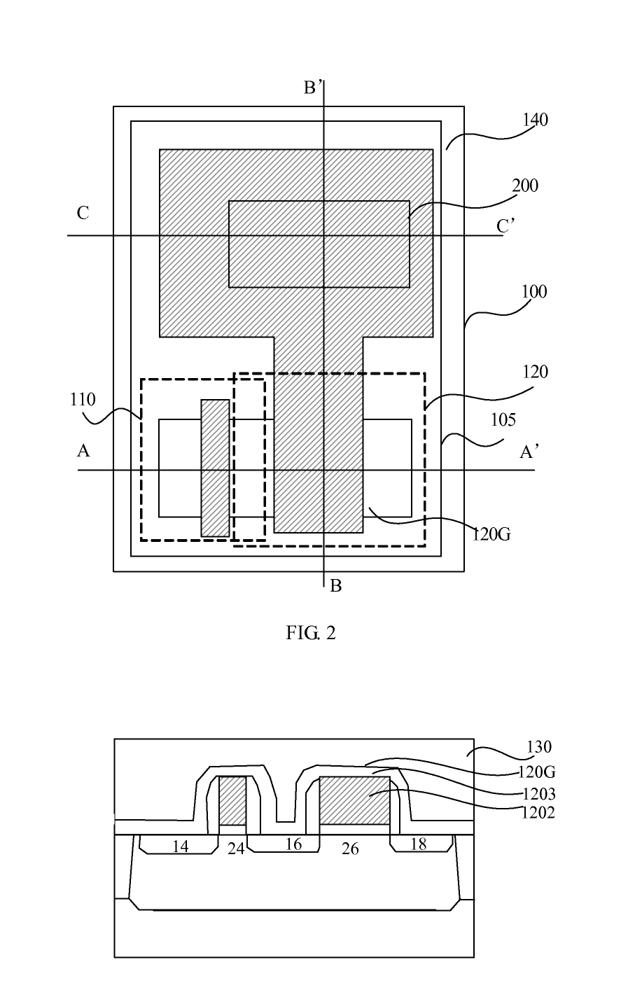

FIG. 2 is a schematic structural view of a single-gate non-volatile flash memory cell according to one embodiment of the present disclosure. As shown in FIG. 2, the single-gate non-volatile flash memory cell includes a semiconductor structure. The semiconductor structure includes a substrate 100 in which a doped well 105 with a first conducting type is disposed. A controlling-gate transistor 110 and a floating-gate transistor 120 are disposed in and on the doped well 105. The controlling-gate transistor's source and the floating-gate transistor's drain share a same doping region. The floating-gate transistor 120 has a floating-gate structure which includes a floating-gate part 120G and a floating-gate extension part 140. An interlayer dielectric (ILD) layer is disposed on the semiconductor structure, which is not shown in FIG. 2. The memory cell further includes a movable switch 200.

Specifically, the substrate 100 may include monocrystalline silicon, polysilicon or amorphous silicon. Or else, the substrate 100 may include silicon, germanium, GaAs, or silicon germanium compound. The substrate 100 may include an epitaxial layer or a silicon-on-insulator structure. The substrate 100 may include other suitable semiconductor materials, which is not illustrated here.

The first conducting type may be N type or P type. The following description will employ the first conducting type being N type and a second conducting type being P type as an example. The N-type well 105 is disposed in the substrate 100. Formation of the N-type well 105 is well known for those skilled in the art. For example, a region of the N-type well is defined on the substrate 100 by applying a lithographic process first; and then, an ion doping process with N-type ions like phosphorus ions is performed to form the N-type well.

The controlling-gate transistor 110 and the floating-gate transistor 120, which are both PMOS transistors, are disposed in and on the N-type well. It could be understood that if the well 105 is a P-type well, the transistors should be NMOS transistors. The controlling-gate transistor 110 is adapted for performing a read or write operation to the memory cell, and the floating-gate transistor 120 is adapted for data storage. An ILD layer 130 is disposed on the controlling-gate transistor 110 and the floating-gate transistor 120. Other interconnection layers may be disposed on the ILD layer which is adapted for insulating the interconnection layers.

The ILD layer 130 normally includes SiO₂ or doped SiO₂, such as undoped silicon glass (USG), Borophosphosilicate glass (BPSG), borosilicate glass (BSG), phosphosilicate glass (PSG), and the like.

The above described semiconductor structure may include a controlling-gate transistor and a floating-gate transistor of a conventional single-gate memory cell, which is well known for those skilled in the art and will not be illustrated in detail here.

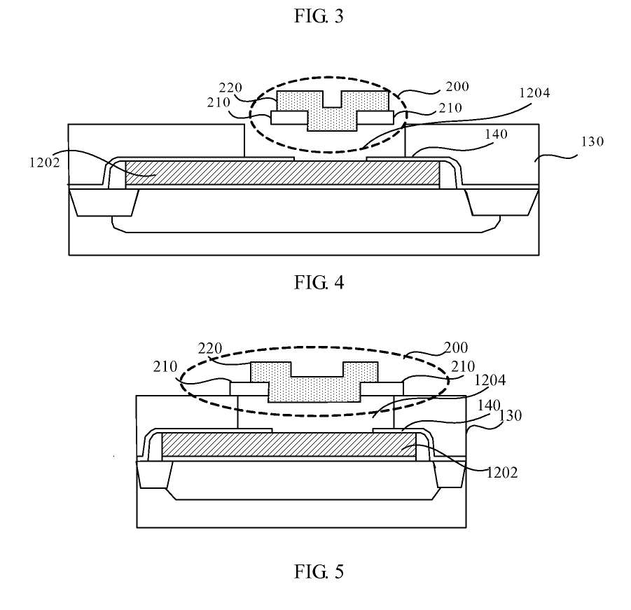

FIG. 3 is a schematic cross-sectional view illustrating the structure shown in FIG. 2 along A-A′ direction. In the embodiment, referring to FIG. 3, the floating-gate structure includes: the floating-gate part 120G and the floating-gate extension part 140. The floating-gate structure includes a floating gate 1202 and an insulating layer 1203 disposed on the floating gate 1202. It could be understood that a portion of the floating gate 1202 and a portion of the insulating layer 1203 are included in the floating-gate extension part 140. The floating gate 1202 may be a polysilicon layer, as an example. The insulating layer 1203 may include silicon nitride or silicon oxynitride, which is adapted for protecting the semiconductor structure in regions where metal contacts are not to be formed. Therefore, the metal contacts are only formed in desired regions of the semiconductor structure. The ILD layer 130 overlays the insulating layer 1203.

FIG. 4 is a schematic cross-sectional view illustrating the structure shown in FIG. 2 along B-B′ direction. Referring to FIG. 4, the memory cell further includes the movable switch 200 which is arranged above the floating-gate structure. In the embodiment, the movable switch 200 is arranged above the floating-gate extension part 140. There is an opening 1204 in the floating-gate extension part 140. The opening 1204 exposes the floating gate 1202. The position of the opening 1204 corresponds to the position of the movable switch 200. The movable switch 200 includes: a support component 210 and a conductive interconnection component 220. The support component 210 has one end connecting to the border of the conductive interconnection component 220 and another end connecting to the ILD layer 130. The conductive interconnection component 220 suspends above the opening 1204 because it is supported by the support component 210. When a voltage is applied to the conductive interconnection component 220, the conductive interconnection component 220 may be forced to enter the opening 1204, come into contact with and electrically connect to the floating-gate 1202 due to the electrostatic force. In order to electrically connect the floating-gate 1202 and the conductive interconnection component 220 with a relatively low voltage (for example, from about 3 V to about 6 V), the thickness of the ILD layer 130 is preferably selected within a range from about 0.2 μm to about 1 μm.

In other embodiments, the floating-gate structure may only include the floating-gate part 120G, without including the floating-gate extension part 140. The movable switch may be arranged above the floating-gate part 120G in a similar way to the embodiment described above.

FIG. 5 is a schematic cross-sectional view illustrating the structure shown in FIG. 2 along C-C′ direction. As an example, the support component 210 includes insulating material and the conductive interconnection component 220 includes metal. As shown in FIG. 5, the support component 210 may be configured as pins (lead foots) disposed on symmetrical opposite sides of the conductive interconnection component 220, or as an insulating layer such as a silicon nitride layer disposed on the periphery of the conductive interconnection component 220. One end of the support component 210, which connects to the conductive interconnection component 220, is disposed under the conductive interconnection component 220. Another end of the support component 210, which connects to the ILD layer 130, is disposed on the ILD layer 130. Therefore, the conductive interconnection component 220 can suspend above the opening due to the support component 210. When a voltage is applied to the conductive interconnection component 220, the conductive interconnection component 220 and the floating-gate 1202 will attract each other due to the electrostatic force. Therefore, the support component 210 bends, and the conductive interconnection component 220 enters the opening 1204, comes into contact and electrically connects to the floating-gate 1202. When the conductive interconnection component 220 and the floating-gate 1202 are electrically connected, the support component 210 provides rigid support, which increases the mechanical fatigue resistance. The support component 210 may include a material other than silicon nitride, for example, SiO₂, SiON, polysilicon, silicon, or the like.

In order to make the support component 210 bend but not fracture when the conductive interconnection component 220 and the floating-gate 1202 are electrically connected, the shape, thickness and width of the support component 120 should be selected by considering the thickness of the conductive interconnection component 220. Optionally, the support component 210 may be configured as one or more strip structures extending across two sides of the conductive interconnection component 220. The support component 210 includes extension portions which are connected with the ILD layer and extended from two sides of the conductive interconnection component 220. The extension portions may be linear pins, meander line pins, or bulk pins distributed all over the periphery of the conductive interconnection component 220. In order to avoid cracking of the support component 210 with the above described structures, the thickness of the support component 120 is selected within a range from about 500 Å to about 3000 Å, and the thickness of the conductive interconnection component 220 is selected within a range from about 500 Å to about 5000 Å. Within the above range, it is ensured that the support component may not fracture regardless of the width thereof. However, in practice, the thickness of the support component 210 and the thickness of the conductive interconnection component 220 are selected in consideration of the width of the support component 210.

Optionally, the opening includes a first portion in the ILD layer and a second portion which is corresponding to the center of the first portion and disposed in the insulating layer. In other words, the second portion is disposed in the floating-gate extension part. The first portion and the second portion are connected, constituting the opening.

Optionally, the conductive interconnection component includes a convex portion corresponding to the position of the opening's second portion. In addition, the conductive interconnection component corresponds to the central region of the opening, i.e., the conductive interconnection component is smaller than the opening, which makes the conductive interconnection component 220 be capable of passing through the opening 1204 without touching the sidewalls of the opening 1204. Therefore, the convex portion of the conductive interconnection component 220 may be electrically connected with the floating-gate 1202 through the opening's second portion in the floating-gate extension part 140. Alternatively, the opening's second portion in the floating-gate extension part may be disposed within the central region of the opening's first portion in the ILD layer, and the position of the convex portion corresponds to the position of the opening's second portion.

In order to establish a nice electrical connection between the conductive interconnection component 220 and the floating-gate 1202 when the conductive interconnection component 220 is electrically connected with the floating-gate 1202 through the opening 1204, preferably, the convex portion of the conductive interconnection component 220 corresponding to the floating-gate structure is configured to have a square cross-section, which has an area ranging from about 0.01 μm² to about 25 μm².

The size of the opening 1204 may be selected according to the size of the conductive interconnection component, ensuring that the conductive interconnection component is spaced at a distance from the opening's sidewalls. For example, the length and width of the opening may be configured as about 1.5 times to about 3 times of the length and width of the conductive interconnection component.

In other embodiments, the floating-gate structure may only include the floating-gate, without including the insulating layer. Accordingly, the opening only includes the first portion in the ILD layer.

The conductive interconnection component suspends above the opening 1204. In a write operation, a positive voltage of 5 V is applied to the conductive interconnection component 220. Due to the electrostatic force, the conductive interconnection component 220 and the floating-gate conductive layer (which is the floating-gate 1202) attract and come into contact with each other. Therefore, electrical connection is established and positive charges are stored in the floating-gate. In an erase operation, a negative voltage of 5 V is applied to the conductive interconnection component 220. Due to the electrostatic force, the conductive interconnection component 220 and the floating-gate conductive layer (which is the floating-gate 1202) attract and come into contact with each other. Therefore, electrical connection is established and the positive charges stored in the floating-gate are erased.

The movable switch is configured in the memory device according to the embodiments of the present disclosure, so that write and erase operations can be directly performed to the floating-gate. However, in a conventional memory device, erase operation is normally performed by applying the mechanism of hot electron tunneling or electron tunneling, in which a high operating voltage is necessary. Normally the operating voltage of a conventional erase operation ranges from about 7 V to about 20 V. Therefore, high-voltage devices are necessary when manufacturing conventional memory cells, resulting in a complicated manufacturing process. Erasing and writing the memory cell provided by the embodiments of the present disclosure are realized by the movable switch to charge/discharge the memory cell, which simplifies the control circuit and reduces the manufacturing costs. Besides, in the conventional single-gate memory cell, the hot electron tunneling and electron tunneling occurring in repeated erase operations may lead to the transistor failure. When erasing the memory cell provided by the embodiments of the present disclosure, a high voltage is no longer required, which may improve the reliability of the product. Further, in the embodiment of the present disclosure, the power consumption generated in the conventional write operation which is performed to the floating-gate by applying hot electrons may be reduced. Further, the write and erase operations are performed directly to the floating-gate in the embodiments, thereby significantly reducing the operation period and improving the working efficiency.

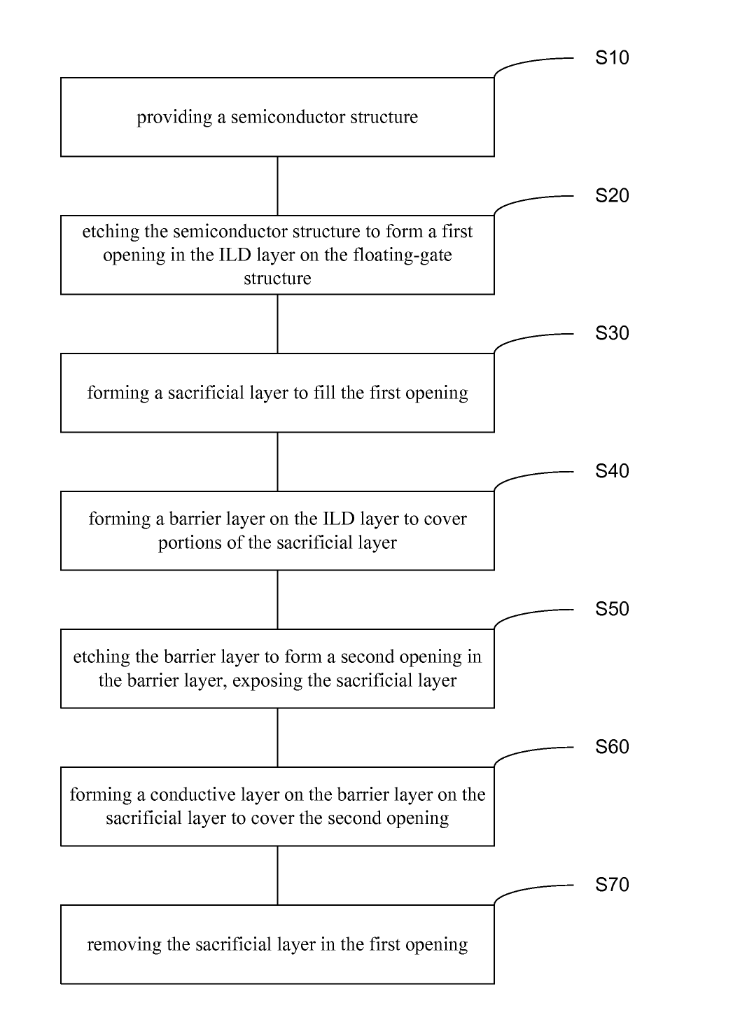

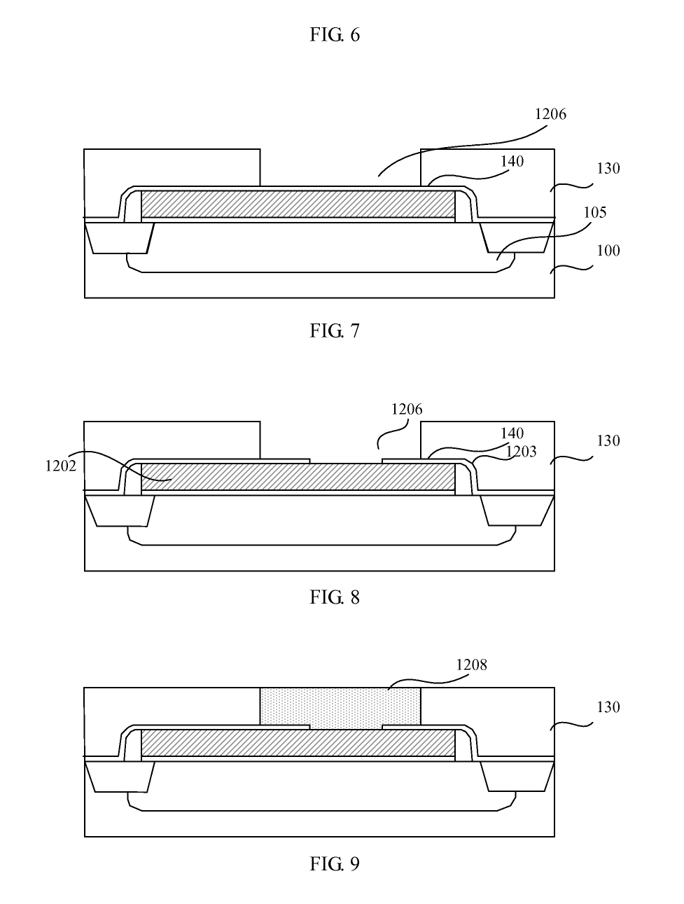

FIG. 6 is a flow chart illustrating a method for forming a single-gate non-volatile flash memory cell according to an embodiment of the present disclosure. The method, together with the single-gate non-volatile flash memory cell formed with the method, will be further illustrated with reference to FIG. 6.

The method for forming a single-gate non-volatile flash memory cell includes the following steps.

At step S10, a semiconductor structure is provided.

Specifically, referring to FIG. 7, the semiconductor structure includes a substrate 100 in which an N-type doped well 105 is disposed. A controlling-gate transistor and a floating-gate transistor (which are not shown in FIG. 7) are disposed in and on the doped well 105. The controlling-gate transistor's source and the floating-gate transistor's drain have a same doping region. The floating-gate transistor has a floating-gate structure. An interlayer dielectric (ILD) layer 130 is disposed on the controlling-gate transistor and the floating-gate transistor.

At step S20, the semiconductor structure is etched to form a first opening 1206 in the ILD layer on the floating-gate structure.

Specifically, referring to FIG. 8, lithographic and etching processes which are well known for those skilled in the art may be applied to form the first opening 1206. For example, a photoresist layer is formed on the semiconductor structure by applying a spin-on process. Thereafter, a pattern in a mask corresponding to the first opening is transferred to the photoresist layer by applying an exposure process. Thereafter, a portion of the photoresist corresponding to the pattern is removed with developer solution, thereby forming a patterned photoresist.

The etching process may be any conventional etching process, such as a chemical etching process or a plasma etching process. In the embodiment, a plasma etching process is applied. The plasma etching process employs one or more selected from CF₄, CHF₃, CH₂F₂, CH₃F, C4F₈ and C₅F₈ as etch gas to etch the ILD layer 130 until the floating-gate structure is exposed, thus the first opening is formed.

Normally, the floating-gate structure includes a floating-gate part (not shown in FIG. 8) and a floating-gate extension part 140. The floating-gate structure may further include a floating-gate 1202 and an insulating layer 1203 disposed on the floating-gate 1202. It could be understood that a portion of the floating-gate 1202 and a portion of the insulating layer 1203 are included in the floating-gate extension part 140. The floating-gate 1202 may be a polysilicon layer, as an example. The insulating layer 1203 may include silicon nitride or silicon oxynitride, which is adapted for protecting the semiconductor structure in regions metal contacts are not to be formed.

Specifically, the step for etching the semiconductor structure to form the first opening in the ILD layer on the floating-gate structure is performed as follows.

The ILD layer is etched to form a first portion of the first opening.

Thereafter, a patterned photoresist layer is formed on the floating-gate extension part 140 exposed by the first portion, a portion of the insulating layer 1203 is exposed by the patterned photoresist layer. Then the exposed insulating layer is etched, which forms a second portion of the first opening in the floating-gate extension part. The first portion in the ILD layer and the second portion in the floating-gate extension part constitute the first opening 1206 which exposes a portion of the floating-gate 1202 in the floating-gate extension part 140.

Optionally, the second portion in the floating-gate extension part corresponds to the central region of the first portion in the ILD layer.

At step S30, the first opening is filled to form a sacrificial layer.

Specifically, referring to FIG. 9, a sacrificial layer 1208 may be formed by applying a CVD or spin-on process. For example, a photoresist layer is coated by applying a spin-on process, and the photoresist layer can be taken as the sacrificial layer. The first opening is filled until the top surface of the sacrificial layer 1208 levels with the top surface of the ILD layer 130.

At step S40, a barrier layer is formed on the ILD layer 130, covering portions of the sacrificial layer 1208.

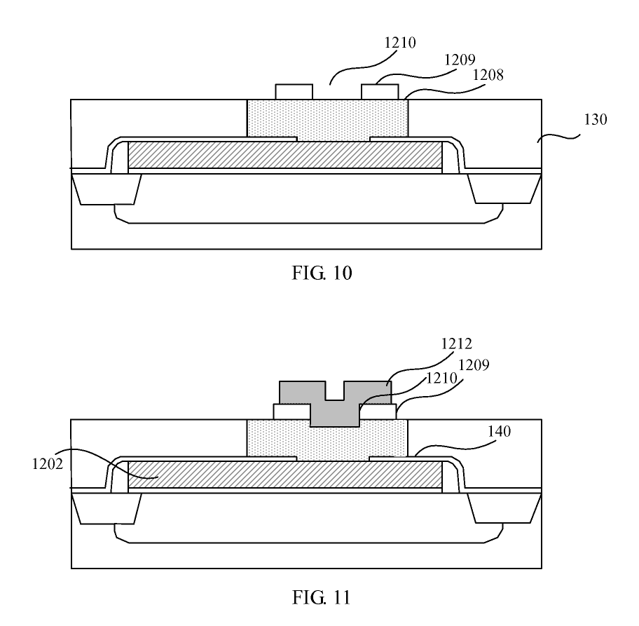

Specifically, referring to FIG. 10, a barrier layer 1209 which may include silicon nitride is formed on the ILD layer 130 by CVD.

In a specific example, the barrier layer covers a portion of the sacrificial layer 1208 corresponding to the central region of the first opening, and a portion of the sacrificial layer 1208 within a region corresponding to the periphery of the first opening is exposed.

At step S50, the barrier layer is etched to form a second opening which exposes a portion of the sacrificial layer.

Specifically, referring to FIG. 10, a patterned photoresist layer is formed on the barrier layer and a second opening 1210 is formed by etching the barrier layer with the patterned photoresist layer as a mask. The second opening 1210 exposes a portion of the sacrificial layer. The barrier layer may be etched with an etching process, such as a plasma etching process, which is well known in the art.

Optionally, the position of the second opening corresponds to the position of the first opening's second portion.

At step S60, a conductive layer is formed on the barrier layer. The conductive layer covers the second opening.

Specifically, referring to FIG. 11, a conductive layer 1212 is formed by performing a PVD process to fill the second opening 1210 until a metal layer is formed to overlay the second opening 1210. The target in the PVD process may be metal, for example, aluminum. Processing parameters of the PVD process may include: temperature from about 250° C. to about 500° C., chamber pressure from about 10 mTorr to about 18 mTorr, DC power from about 10000 W to about 40000 W, and Ar gas flow rate from about 2 sccm to about 20 sccm.

Further, an etching process may be performed to remove a portion of the conductive layer on the barrier layer 1209, in order that only portions of the conductive layer which are on the periphery of the second opening 1210 (i.e., on the barrier layer corresponding to the sacrificial layer) and in the second opening 1210 are kept. When forming the conductive layer 1212, the deposition material is likely to fill the second opening 1210 preferentially, so the conductive layer 1212 may include a convex portion towards the floating-gate extension part 140 in the opening 1210, i.e., the convex portion is disposed in the region corresponding to the first opening's second portion in the floating-gate extension part 140. As a result, in the memory cell formed subsequently, the conductive layer may come into contact with the floating-gate 1202 through the first opening's second portion in the floating-gate extension part 140 due to electrostatic force, which forms an electrical interconnection.

At step S70, the sacrificial layer in the first opening is removed.

Specifically, referring still to FIG. 11, the sacrificial layer may be removed by a washing or ashing process. Other than the materials of the sacrificial layer described above, the sacrificial layer may include any suitable material which may be easily removed by a washing or ashing process. Thus, the structure shown in FIG. 4 is formed.

Optionally, the barrier layer and the second opening correspond to the central region of the first opening. The first opening's second portion in the floating-gate extension part corresponds to the central region of the first opening's first portion in the ILD layer. And the convex portion of the conductive layer towards the floating-gate extension part corresponds to the first opening's second portion in the floating-gate extension part.

Optionally, the first doping type may be P type and the second doping type may be N type.

Optionally, in other embodiments, a floating-gate extension part may not be configured in the memory cell and a movable switch is formed directly above the floating-gate part.

Further, an embodiment of the present disclosure provides a single-gate non-volatile flash memory device including an array of the above described single-gate non-volatile flash memory cells.

The disclosure is disclosed, but not limited, by preferred embodiments as above. Based on the disclosure of the disclosure, those skilled in the art can make any variation and modification without departing from the scope of the disclosure. Therefore, any simple modification, variation and polishing based on the embodiments described herein is within the scope of the present disclosure.

What is claimed is:

1. A single-gate non-volatile flash memory cell, comprising:
a semiconductor structure, comprising a substrate, a doped well with a first conducting type in the substrate, a controlling-gate transistor and a floating-gate transistor which are in and on the doped well, wherein the controlling-gate transistor's source and the floating-gate transistor's drain share a same doped region, the floating-gate transistor comprises a floating-gate structure, and an interlayer dielectric layer is disposed on the semiconductor structure; and
a movable switch disposed above the floating-gate structure, wherein there is an opening corresponding to the movable switch in the ILD layer, and the opening exposes the floating-gate structure, and the movable switch comprises:
a support component and a conductive interconnection component, wherein one end of the support component connects to the border of the conductive interconnection component, another end of the support component connects to the ILD layer, so that the conductive interconnection component suspends above the opening, the conductive interconnection component electrically connects to the floating-gate structure when a voltage is applied to the conductive interconnection component.

2. The single-gate non-volatile flash memory cell according to claim 1, wherein the floating-gate structure comprises a floating-gate part and a floating-gate extension part,
wherein the movable switch is disposed above the floating-gate extension part, there is an opening corresponding to the movable switch in the ILD layer, and the opening exposes the floating-gate extension part, the movable switch comprises: a support component and a conductive interconnection component, wherein one end of the support component connects to the border of the conductive interconnection component, another end of the support component connects to the ILD layer, so that the conductive interconnection component suspends above the opening, the conductive interconnection component electrically connects to the floating-gate extension part when a voltage is applied to the conductive interconnection component.

3. The single-gate non-volatile flash memory cell according to claim 2, wherein the first doping type is N type and a second doping type is P type.

4. The single-gate non-volatile flash memory cell according to claim 2, wherein the first doping type is P type and a second doping type is N type.

5. The single-gate non-volatile flash memory cell according to claim 2, wherein the support component comprises insulating material, the support component are configured as pins distributed on two symmetrical opposite sides of the conductive interconnection component, the one end the support component connecting to the conductive interconnection component is disposed under the conductive interconnection component, and the another end of the support component connecting to the ILD layer is disposed on the ILD layer.

6. The single-gate non-volatile flash memory cell according to claim 5, wherein the floating-gate structure comprises a floating-gate and an insulating layer on the floating-gate, the opening comprises a first portion in the ILD layer, and a second portion which is in the insulating layer of the floating-gate extension part and corresponds to the first portion's central region,
and the opening's second portion corresponds to the first portion's central region.

7. The single-gate non-volatile flash memory cell according to claim 6, wherein the conductive interconnection component comprises a convex portion towards the floating-gate extension part, and the convex portion corresponds to the opening's second portion in the floating-gate extension part.

8. The single-gate non-volatile flash memory cell according to claim 2, wherein the conductive interconnection component corresponds to the opening's central region.

9. The single-gate non-volatile flash memory cell according to claim 2, wherein the conductive interconnection component comprises metal.

10. A single-gate non-volatile flash memory device comprising an array of single-gate non-volatile flash memory cells according to claim.

11. A method for forming a single-gate non-volatile flash memory cell, comprising:
providing a semiconductor structure, wherein the semiconductor structure comprises a substrate, a doped well with a first conducting type in the substrate, a controlling-gate transistor and a floating-gate transistor which are in and on the doped well, wherein the controlling-gate transistor's source and the floating-gate transistor's drain share a same doped region, the floating-gate transistor comprises a floating-gate structure, and an interlayer dielectric layer is disposed on the semiconductor structure;
etching the semiconductor structure to form a first opening in the ILD layer on the floating-gate structure;
forming a sacrificial layer to fill the first opening;
forming a barrier layer on the ILD layer, the barrier layer covering portions of the sacrificial layer;
etching the barrier layer to form a second opening in the barrier layer, the second opening exposing the sacrificial layer;
forming a conductive layer on the barrier layer, the conductive layer covering the second opening; and
removing the sacrificial layer in the first opening.

12. The method for forming a single-gate non-volatile flash memory cell according to claim 11, wherein the floating-gate structure comprises a floating-gate part and a floating-gate extension part,
and forming the first opening in the ILD layer on the floating-gate structure is to form the first opening in the ILD layer on the floating-gate extension part.

13. The method for forming a single-gate non-volatile flash memory cell according to claim 12, wherein the floating-gate structure comprises a floating-gate and an insulating layer on the floating-gate, and the step of etching the semiconductor structure to form the first opening comprises:
etching the ILD layer to form a first portion of the first opening; and
etching the insulating layer exposed by the first opening's first portion to form the first opening's second portion in the insulating layer.

14. The method for forming a single-gate non-volatile flash memory cell according to claim 12, wherein the barrier layer corresponds to the first opening's central region, and the second opening corresponds to the first opening's central region.

15. The method for forming a single-gate non-volatile flash memory cell according to claim 12, wherein the insulating layer comprises silicon nitride.

16. The method for forming a single-gate non-volatile flash memory cell according to claim 12, wherein the conductive layer comprises metal.
